(19) United States
(12) Patent Application Publication
(10) Pub. No.: US 2005/0280081 A1
(43) Pub. Date: Dec. 22, 2005

(54) Semiconductor devices having bonded interfaces and methods for making the same

(75) Inventors: David M. Isaacson, Boston, MA (US); Gianni Taraschi, Somerville, MA (US); Eugene A. Fitzgerald, Windham, NH (US)

Correspondence Address: Jamie H. Rose;Wolf, Greenfield & Sacks, P.C., 600 Atlantic Avenue, Boston, MA, 02210-2206, US

(73) Assignee: Massachusetts Institute of Technology, Cambridge, MA (US)

(21) Appl. No.: 10/956,485

(22) Filed: Oct. 1, 2004

Related U.S. Application Data
(63) Continuation-in-part of application No. 10/869,463, filed on Jun. 16, 2004.

(51) Int. Cl. H01L 31/0336

(52) U.S. Cl. 257/335

(57) ABSTRACT

A semiconductor-based structure includes first, second, and intermediate layers, with the intermediate layer bonded directly to the first layer, and in contact with the second layer. Parallel to the bonded interface, the lattice spacing of the second layer is different than the lattice spacing of the first layer, though first and second layers are each formed of essentially the same semiconductor. A method for making a semiconductor-based structure includes directly bonding a first layer to an intermediate layer, and providing a second layer in contact with the intermediate layer.

### RELATED APPLICATIONS

This application is a Continuation-in-Part of application Ser. No. 10/869,463, filed Jun. 16, 2004, which is incorporated herein by reference.

### BACKGROUND OF INVENTION

1. Field of Invention

The invention relates to semiconductor-based electronic devices, and, more particularly, to the structure and fabrication of semiconductor-based substrates and electronic devices that include strained semiconductor layers.

2. Discussion of Related Art

Some advanced semiconductor-based devices include a semiconductor layer that is strained by application of a stress to provide improved performance of the devices. For example, metal-oxide-semiconductor (MOS) transistors having a channel formed in strained silicon or strained Si_{1-y}Ge_{y} formed on unstrained, or relaxed, Si₁₋ₓGeₓ, can exhibit improved carrier mobility in comparison to traditional p-type MOS (PMOS) and n-type MOS (NMOS) transistors. Strained-layer MOS transistors can be formed on “virtual substrates,” which can include a strained layer to provide compatibility with traditional silicon-based fabrication equipment and methods that were designed for use with conventional silicon wafers. A virtual substrate, in contrast to a conventional wafer, can includes a strained silicon layer grown on a relaxed and/or graded Si₁₋ₓGeₓ layer in turn grown on a silicon substrate.

To fabricate high-performance devices, thin strained layers of semiconductors, such as Si, Ge, or Si_{1-y}Ge_{y}, can be grown on a relaxed Si₁₋ₓGeₓ layer of a virtual substrate. The resulting biaxial tensile or compressive strain of the thin layers alters their carrier mobilities, enabling the fabrication of high-speed and/or low-power devices.

The relaxed Si₁₋ₓGeₓ layer of a virtual substrate can in turn be prepared by, e.g., direct epitaxy on Si, or by epitaxy on a graded SiGe buffer layer in which the lattice constant of the SiGe material has been gradually increased over the thickness of the buffer layer. The virtual substrate may also incorporate buried insulating layers, in the manner of a silicon-on-insulator (SOI) wafer. Deposition of a relaxed graded SiGe buffer layer enables engineering of the in-plane lattice constant of a relaxed Si₁₋ₓGeₓ virtual substrate layer (and therefore the amount of strain the relaxed layer will induce in a strained silicon layer or other overlying layer,) while also reducing the introduction of threading dislocations, which can be deleterious to device layers fabricated on the top-most region of the wafer. The lattice constant of unstrained Si₁₋ₓGeₓ is larger than that of Si, and is a function of the amount of Ge in the Si₁₋ₓGeₓ alloy.

Unfortunately, Si₁₋ₓGeₓ-based substrates can increase the complexity of device fabrication. For example, source and drain contact metallurgy is altered, and interdiffusion between Si₁₋ₓGeₓ layers and neighboring layers can occur. As an alternative to a Si₁₋ₓGeₓ-based substrate, strained silicon can be provided on an oxide layer of a substrate. The presence of the oxide layer, however, forces process modifications. Further, the presence of oxide layers and Si₁₋ₓGeₓ layers can lead to reduced thermal conductivity of substrates in comparison to conventional silicon wafer substrates. A reduced thermal conductivity can cause an increase in the difficulty of removing heat at a sufficient rate from devices formed on a substrate.

### SUMMARY OF INVENTION

An embodiment of the invention arises from the realization that two layers formed of the same semiconducting material, but having different levels of strain, can be bonded to one another via a thin intermediate layer to maintain a strain in at least one of the layers while moving an interface containing misfit dislocations away from that strained layer and/or reducing threading dislocations in the strained layer. Thus, for example, the presence of undesirably thick strain-inducing layers can be eliminated, while also moving misfit dislocations away from an interface of the strained layer.

Accordingly, in one aspect, the invention features a semiconductor-based structure. The structure includes first and second layers of essentially the same semiconductor, though having different lattice spacings, and an intermediate layer disposed between the first and second layers, and having a substantially different composition than that of the semiconductor. The intermediate layer is bonded directly to the first layer at a first interface, and in direct contact with the second layer at a second interface.

In another aspect, the invention features an electronic device. The device includes a substantially strain-free substrate layer and a tensilely strained layer both formed of silicon, an intermediate layer disposed between the substantially strain-free substrate layer and the tensilely strained layer, and formed of silicon and germanium, a gate dielectric layer adjacent to the tensilely strained layer, and a gate in contact with the gate dielectric layer. The intermediate layer is directly bonded to the substantially strain-free substrate layer, and in contact with the tensilely strained layer. The intermediate layer has a thickness that provides effective thermal conduction.

In another aspect, the invention features a method for making a semiconductor-based structure. The method includes providing first and second layers both formed of the same semiconductor, though the second layer has a different lattice spacing parallel to a surface of the first layer than a lattice spacing of the first layer parallel to the surface, providing an intermediate layer in direct contact with the second layer, contacting the surface of the first layer to a surface of the intermediate layer, and annealing to promote direct atomic bonding between the first and intermediate layers.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a flow diagram of an embodiment of a method for making a semiconductor-based structure, according to principles of the invention;

FIGS. 2a, 2b, and 2c are cross-sectional diagrams that illustrate the making of an example embodiment of a structure via the method illustrated in FIG. 1;

FIG. 3 is a cross-sectional diagram of an embodiment of a semiconductor-based structure, according to principles of the invention;

FIG. 4 is a cross-sectional diagram of an embodiment of an electronic device, according to principles of the invention;

FIG. 5 is a cross-sectional diagram of an embodiment of an electronic device, according to principles of the invention;

FIG. 6 is a flow diagram of an embodiment of a method for making a semiconductor-based structure, according to principles of the invention;

FIGS. 7a, 7b, and 7c are cross-sectional diagrams that illustrate the making of an example embodiment of a structure via the method illustrated in FIG. 1;

FIG. 8 is a cross-sectional diagram of an embodiment of a semiconductor-based structure, according to principles of the invention;

FIG. 9 is a cross-sectional diagram of an embodiment of an electronic device, according to principles of the invention; and

FIG. 10 is a cross-sectional diagram of an embodiment of an electronic device, according to principles of the invention.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,”, “involving,” and variations thereof herein, is meant to encompass the items listed thereafter and equivalents thereof as well as additional items.

The term “MOS” is used herein to refer generally to semiconductor devices that include a conductive gate spaced at least by an insulating layer from a semiconducting channel layer. The terms “SiGe” and “Si₁₋ₓGeₓ” are used in this description, depending on context, to interchangeably refer to silicon-germanium alloys. The term “silicide” is used in this description to refer to a reaction product of a metal, silicon, and optionally other components, such as germanium. The term “silicide” is also used, less formally, to refer to the reaction product of a metal with an elemental semiconductor, a compound semiconductor or an alloy semiconductor.

The term “virtual substrate” as used herein refers to a substrate that includes a strain-inducing semiconductor layer, such as a relaxed SiGe layer. The term “virtual substrate” is also used herein to refer to a substrate including an insulator layer which maintains pre-induced strains in subsequently provided layers. The strain levels thus maintained are analogous to those induced by a strain-inducing semiconductor layer.

For example, a strain of about 1.2% can induced in a SiGe layer by growth on a virtual-substrate SiGe layer, where the Ge concentration difference is approximately 30% (elemental concentrations in alloys are given herein in units of atomic %.)

As described in more detail below, a strained layer can also be bonded to an insulator layer or to a semiconductor layer, and the strain can then be maintained without the presence of the original strain-inducing layer. Thus, language specifying the Ge content of the virtual substrate layer may also apply interchangeably to strained semiconductor layers that are equivalently strained by, and disposed adjacent to, an insulating substrate, where the strain in the semiconductor layers is maintained by the strong interface with the substrate. A strained layer(s) can then be utilized as a channel layer for a MOS device.

The term “directly bonded” is used herein to refer to an interface between two layers that involves direct contact between the two layers. A bonded contact between two layers can be produced after the two layers are each at least partially formed. A bonded contact is distinct from a direct contact first formed by deposition of a material.

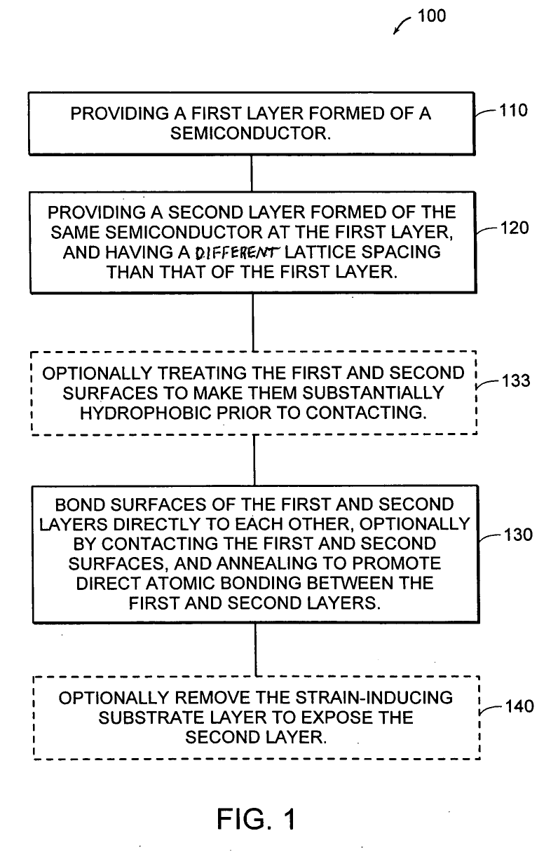

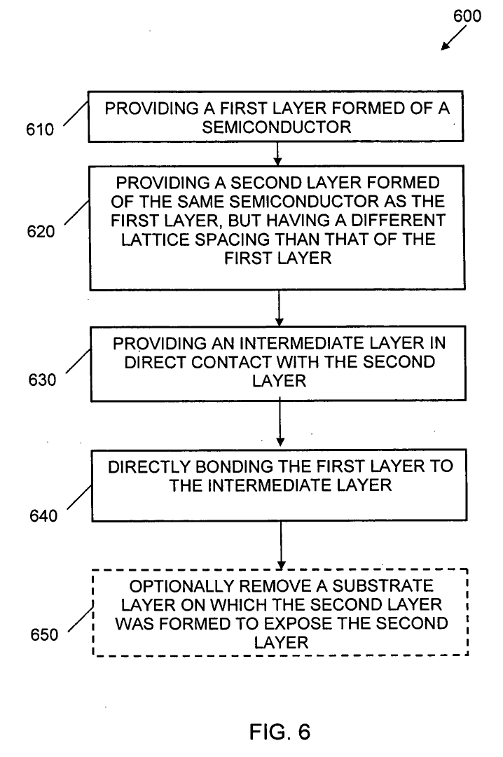

In some embodiments of the invention, described with reference to FIG. 1 through FIG. 5, layers of the same semiconductor are directly bonded. In other embodiments of the invention, described below in more detail with reference to FIG. 6 through FIG. 10, a semiconductor structure includes a thin strained or relaxed SiGe layer that is utilized to separate a bulk silicon layer from a strained silicon layer, thereby reducing the deleterious effects that can otherwise occur when layers of the same material are directly bonded. Such effects include source-drain shorting due to dopant diffusion along interfacial misfit dislocations.

In these latter embodiments, the thickness of the SiGe layer can be chosen so that source and drain contacts are spaced from an interfacial misfit dislocation array, yet the SiGe layer is kept sufficiently thin to retain a high thermal conductivity throughout the structure. Thus, these embodiments can eliminate the presence of strain-inducing layers having a thickness that can lead to substantial undesirable thermal effects.

The present invention will now be described by way of specific, non-limiting, examples. It should be understood that the invention applies to substrates, devices, and fabrication methods beyond those discussed here. Specific materials structures, devices, and fabrication steps are meant for illustrative purposes only, and are non-limiting.

With reference to FIG. 1, one embodiment of the invention, in which two layers formed of the same semiconductor are directly bonded, is described in broad overview. In this embodiment, a strained semiconductor layer can be directly bonded to a layer or substrate formed of the same semiconductor, though having a different lattice spacing, i.e., a different strain. The strained semiconductor layer can be advantageously utilized for fabrication of semiconductor-based devices. For example, a strained silicon layer can be directly bonded to an unstrained silicon substrate, and can then be utilized as a channel layer for a MOS device. As used herein, “directly bonded” refers to a bond between two layers that involves direct contact between the two layers.

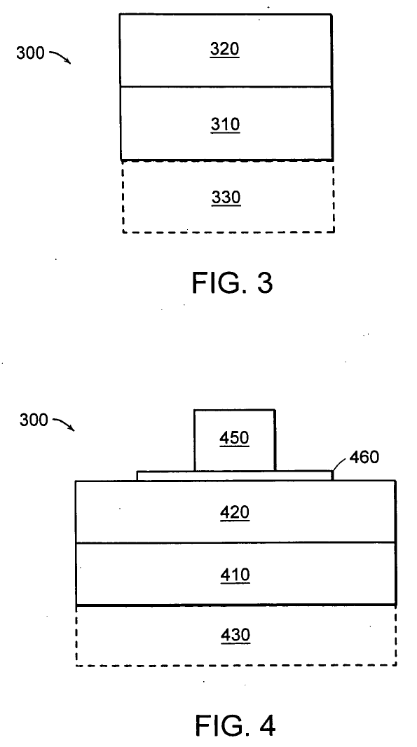

FIG. 1 is a flowchart of an embodiment of a method 100 for making a semiconductor-based structure, according to principles of the invention. Some examples of structures that can be fabricated via the method 100 are described below with reference to FIGS. 3, 4, and 5. The method 100 includes providing a first layer formed of a semiconductor (Step 110), providing a second layer formed of essentially the same semiconductor as the first layer, but having a different strain than a strain of the first layer (Step 120), and bonding the first layer directly to the second layer (Step 130). The order herein of the description or listing of steps of the method 100 should not be construed to require a particular temporal sequence nor to preclude simultaneity of steps.

The semiconductor of the first and second layers is the same material if the layers are formed from essentially the same semiconducting element, formed from the same semiconducting alloy having essentially the same composition in each layer, or formed of essentially the same semiconducting compound. As will be understood by one having ordinary skill in the semiconductor arts, two semiconductors that are essentially the same may include different types and/or amounts of unintentional impurities, intentional impurities, and or crystalline defects. The word “essentially” is used herein to accommodate small variations in composition that have an insignificant or minor effect on the beneficial features of embodiments of substrates according to principles of the invention.

The first and second layers can have a common crystallographic orientation after bonding. That is, the first and second layers can be oriented, prior to bonding (Step 130), so that no tilt or twist misorientation exists between the layers when they are brought into contact and bonded. The layers can be bonded at substantially planar surfaces to provide a bonded interface that is free of voids. Moreover, the surfaces of the two layers are preferably provided with the same crystallographic orientation. Interfacial defects associated with misorientation can be reduced in density or eliminated by reducing or eliminating misorientation prior to bonding.

In alternative embodiments of the invention, the surfaces of the two layers have different crystallographic orientations. For example, a (100)-oriented surface can be bonded to (111)-oriented surface, or surfaces that are slightly off-cut from common orientations can be bonded.

The difference in strain between the first and second layers can manifest itself as a difference in a lattice spacing of the two layers along a direction parallel to the bonded interface. For example, if the two layers are formed of silicon, a lattice spacing of the silicon, parallel to the interface, can be greater in the second layer than in the first layer.

In some embodiments, according to principles of the invention, the second layer is strained while the first layer is substantially unstrained. Thus, for example, though the two layers have the same crystallographic structure, a lattice constant of the second layer can be distorted in comparison to a corresponding undistorted lattice constant of the first layer.

Prior to bonding, the first and second layers are preferably provided with root-mean-square (RMS) surface roughness values of about 0.5 nm or less on a 10 μm×10 μm scale. A suitable roughness can be obtained on, for example, a virtual substrate by chemo-mechanical polishing (CMP) utilizing a KOH-stabilized colloidal silica polishing agent. A strained silicon second layer can be grown, for example, on the polished virtual substrate. Deposition of strained silicon can proceed at relatively low temperatures to preserve a suitably flat surface.

According to principles of the invention, the first layer can be, for example, a substantially unstrained silicon surface layer provided on a SOI substrate, or can be, for example, a conventional silicon wafer. The second layer can be formed, and strained, by, for example, depositing silicon on a virtual substrate. The virtual substrate can have a strain-inducing surface layer, such as a SiGe layer, on which a silicon second layer is grown. The composition of the SiGe layer can be selected to provide a desired level of strain in the silicon second layer.

The strain-inducing substrate layer can be formed by co-depositing silicon and germanium at a temperature in a range of, for example, about 300° C. to about 1000° C. (preferably, about 500° C. to about 600° C.) to improve surface flatness of the SiGe. The second layer can be formed by depositing silicon at a temperature in a range of, for example, about 300° C. to about 1000° C. (preferably, about 500° C. to about 600° C.) The strain-inducing substrate layer is essentially strain-free. Growth of silicon, as well as SiGe, at reduced temperatures, for example, at about 550° C., can provide a smoother layer, and can permit growth of a thicker metastable layer, i.e., a layer in excess of the critical thickness that is substantially free of threading dislocations.

The surfaces can be bonded (Step 130) by, for example, contacting and annealing. Annealing can promote direct atomic bonding between the first and second layers. For silicon bonding, annealing can be performed by heating the first and second layers to a temperature of, for example, greater than about 700° C. For example, annealing can be performed at 800° C. for 2 hours.

Further, the first and second surfaces can be treated prior to contacting to make them substantially hydrophobic prior to contacting (Step 133). Provision of a hydrophobic surface can, prior to bonding (Step 130), reduce or eliminate formation of oxide on the layer surfaces. A hydrophobic surface can be obtained by, for example, bathing in a hydrofluoric acid (HF) solution, for example, a 10% HF solution in water, by volume. A dip in a HF solution also can remove surface oxides.

To remove organic material and/or particles from the surface of a silicon layer, the silicon can be treated in, for example, 3H₂OSO₄:1H₂O₂ for 5 minutes, then in 50H₂₀:1HF for 15 seconds, then in 6H₂₀:1HCl:1H₂O₂ for 15 minutes at 60° C., thus producing a hydrophilic surface. The silicon can then be treated in 10H₂₀:1 HF for 1 minute to remove surface oxide and bond fluorine to the surface, rendering the surface hydrophobic.

Since the bonds formed after initial contact can be weak, annealing is desirable after contacting. Annealing at temperatures above about 700° C. can remove hydrogen bonded to the surfaces of the first and second layers and promote direct bonds between the two layers.

A virtual substrate, or other material, on which the second layer was provided, can be removed after bonding the second layer to the first layer, to expose the second layer (Step 140). Removal of material can commence with mechanical grinding and/or chemical etching. For example, a KOH solution can provide removal of layers and/or portions of layers of a virtual substrate, such as removal of silicon and selective removal of SiGe to an upper concentration level of Ge. For this purpose, 20 wt % KOH at about 65° C. to about 80° C. can be used. To selectively complete removal of a SiGe layer while leaving an adjacent silicon second layer, a chemical etch of nitric acid, acetic acid, and dilute HF (100H₂O:1 HF), for example, can be used.

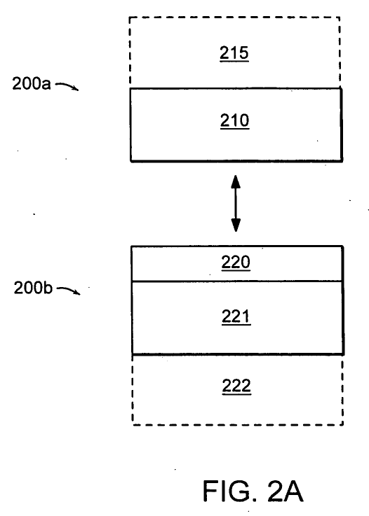

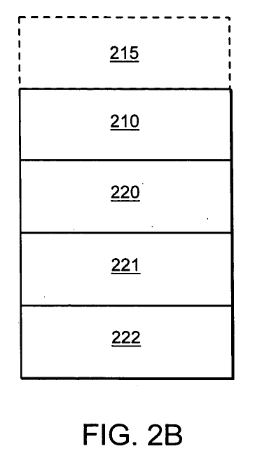

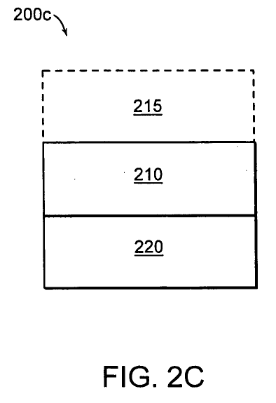

Now referring to FIGS. 2a, 2b, and 2c, embodiments of intermediate structures that illustrate various steps of the method 100 are described. FIG. 2a is a cross-sectional view of a first substrate 200a and a second substrate 200b at a time prior to bonding. The first substrate 200a includes a first layer 210, and can include one or more additional substrate layers 215. The second substrate 200b includes a second layer 220, e.g., a strained silicon layer, formed on a strain-inducing layer 221, e.g., a relaxed SiGe layer, and can include one or more additional layers 222.

FIG. 2b is a cross-sectional diagram of the substrates 200a, 200b as they appear after bonding of the first layer 210 to the second layer 220, as accomplished, for example, by Step 130 as described above. FIG. 2c is a cross-sectional diagram that illustrates a remaining semiconductor-based structure 200c that remains after removal of the strain-inducing layer 221 and any other layers 222. The structure 200c can be used, for example, to fabricate semiconductor-based devices.

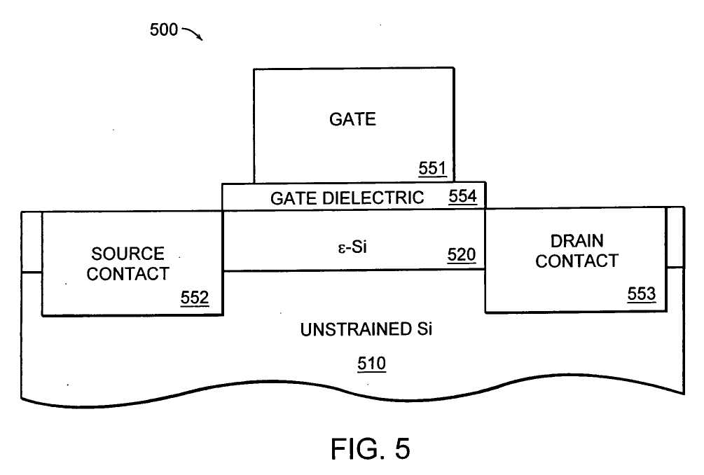

As described in more detail with reference to FIGS. 4 and 5, the method 100 can include steps relating to formation of one or more components having n-type channels and/or one or more components having p-type channels. For example, in relation to forming a n-type channel component, the method 100 can include forming a gate dielectric layer adjacent to the exposed portion of a tensilely strained silicon second layer, and then forming a gate in contact with the gate dielectric layer for mediating a n-type channel in the second layer.

The method 100 can employ thin-film deposition techniques known to one having ordinary skill in the semiconductor fabrication arts. The techniques can be modified to improve surface planarity of the deposited films to mitigate poor planarity can arise during deposition of strained films. A strain-inducing layer and/or a second layer can be deposited, for example, at relatively low temperatures to improve planarity. For example, a strained silicon second layer may be deposited at about 650° C., substantially without causing undulations, on a SiGe strain-inducing layer having a Ge atomic concentration of 20%, while a Si second layer deposition temperature of about 550° C. is preferable for an underlying SiGe layer having a Ge concentration of 50%.

The strain-inducing substrate layer can be, or can be formed on, a graded SiGe layer. The graded SiGe layer can have a grading rate of, for example, 10% Ge/μm, and a thickness in a range of, for example, 2 μm to 9 μm. The graded layer may be grown at a temperature in a range of, for example, 600° C. to 1100° C.

A strain-inducing substrate layer, on which a strained second layer can be grown, can be a relaxed SiGe layer, which can in turn be grown on a graded SiGe layer. The relaxed layer can be formed of Si₁₋ₓGeₓ with a uniform concentration having X in a range of about 20% to 90%. The relaxed layer can have a thickness in a range of, for example, about 0.2 μm to about 2.0 μm. A strained second layer can be formed of strained silicon having a thickness in a range of, for example, about 0.5 nm to about 20 nm.

Deposition may be accomplished, for example, by any suitable epitaxial deposition system, including, but not limited to, atmospheric-pressure CVD (APCVD), low- (or reduced-) pressure CVD (LPCVD), ultra-high-vacuum CVD (UHVCVD), or by molecular beam epitaxy. The epitaxial growth system may be a single-wafer or multiple-wafer batch reactor. The growth system also may utilize a low-energy plasma to enhance the layer growth kinetics.

FIG. 3 is a cross-sectional view of a portion of an embodiment of a semiconductor-based structure 300, according to principles of the invention. The structure 300 includes a first layer 310 and a second layer 320 directly bonded to each other, and can include a substrate 330 in contact with the first layer 310. The structure 300 can be fabricated by, for example, the methods described above.

The first and second layers 310, 320 are formed of the same semiconductor. The semiconductor can be, for example, silicon. The layers 310, 320, as described above, have different levels of strain relative to each other. For example, the second layer 320 can be formed of silicon strained along a direction parallel to the interface between the layers 310, 320, while the first layer 310 can be formed of unstrained silicon. The structure 300 can be used in the fabrication of electronic devices, as described with reference to FIG. 4.

Alternatively, for example, the second layer 320 can be compressed Ge and the first layer 310 can be unstrained Ge. In this example, a compressed Ge film could first be formed on substrates such as Si, SiGe, or Ge. A compressed Ge layer could be created on, for example, a virtual SiGe substrate, and transferred as described previously to Si, SiGe, or Ge substrates. In the case of a Ge substrate, the resulting heterostructure is composed entirely of Ge, but the top surface layer would be compressed Ge and hence could have a superior hole transport characteristic as compared to a relaxed Ge substrate.

According to a general principle of the invention, one may form structures herein referred to as “homochemical heterojunctions.” Typically, a heterojunction's usefulness is related the differences in the energies of electrons and holes on each side of a heterojunction. A typical prior art heterojunction achieves this difference in energy by a change in chemical composition across the heterojunction interface, such as a AlGaAs/GaAs interface or a SiGe/Si interface. Some junctions, according to principles of the invention, have, however, the same composition on either side of a junction. For example, according to principles of the invention, one can produce strained Si/Si and strained Ge/Ge heterojunctions, in which electrons and holes possess different energies across the heterojunction, but the chemical composition across the interface does not change. Such junctions have a strain difference across the heterojunction with little or no chemical difference; the strain difference can thus define the difference in electronic properties alone, without a chemical composition difference.

FIG. 4 is a cross-sectional view of an embodiment of an electronic device 400, according to principles of the invention. The device 400 can be based on the structure 300, and can be fabricated via the method 100. The device 400 includes an unstrained silicon layer 410, a strained silicon layer 420 in contact with the unstrained silicon layer 410, a gate contact 450, and a gate dielectric 460 disposed between the strained silicon layer 410 and the gate contact 450. Application of a voltage to the gate contact can be used to control a channel in the strained silicon layer 420. The device can include a substrate 430 in contact with the unstrained silicon layer 410.

The strained silicon layer 420 can be shared by two or more electronic components, and can be continuous or discontinuous depending on the fabrication steps of a particular embodiment of a device, according to principles of the invention. For example, a shared layer 420, or portions of the layer 420, can extend continuously between two or more devices, or individual devices may be associated with spaced portions of the layer 420. Various implementations of the invention can improve carrier mobilities, for example, the mobility of electrons in a channel formed in the layer 420.

A strained SiGe layer can be formed on the second layer 420 to provide a p-type channel layer for p-type components. For example, improved hole mobilities can be provided by the p-type channel while the underlying second layer 420 can provide a n-type channel for n-type components. The components may be MOS transistors, for example, NMOS and PMOS transistors in an inverter. A suitable value of Y for enhanced hole mobility of Si_{1-y}Ge_{y} in a compressively strained layer grown on silicon can be in a range of, for example, about 20% to 100%. The SiGe layer can have its compressive stress imposed by an underlying layer of, for example, SiGe having a Ge concentration of, for example, about 20%. In some alternative embodiments of the invention, Y is in a range of about 40% to 100%, and an underlying layer of SiGe has a Ge concentration in a range of about 15% to about 50%.

FIG. 5 is a cross-sectional view of an embodiment of a transistor 500 that can be included in a device, such as the device 400, according to principles of the invention. The transistor 500 includes a gate contact 551, source and drain contacts 552, 553, such as silicide contacts, a gate dielectric layer 554, an unstrained silicon layer 510, and a tensilely strained silicon layer 520 bonded to the unstrained silicon layer 510. The unstrained silicon layer 510 preserves the strain in the tensilely strained layer 520 due to the bonding between the layers 510, 520. The tensilely strained silicon layer 520, and the unstrained silicon layer 510 may be shared with other components in a device.

The gate contact 551 can include, for example, doped conductive polycrystalline silicon and/or a silicide. Alternatively, the gate contact 550 may be formed of other conductive materials, such as, polycrystalline SiGe; a metal, e.g., titanium (Ti), tungsten (W), molybdenum (Mo), tantalum (Ta), or iridium (Ir), or metal compounds that provide an appropriate workfunction, e.g., titanium nitride (TiN), titanium silicon nitride (TiSiN), tungsten nitride (WN), tantalum nitride (TaN), tantalum silicide (TaSi), nickel silicide (NiSi), or iridium oxide (IrO₂). The tensilely strained layer 520 may be formed by epitaxially growing Si on, for example, a strain-inducing layer of relaxed Si₁₋ₓGeₓ prior to bonding the grown strained Si to the unstrained silicon layer 510. The source and drain contacts 552, 553 can be formed, for example, by depositing a metal layer and reacting the metal layer with the silicon layers 510, 520.

The gate dielectric 554 is formed on the tensilely strained layer 520. The gate dielectric 554 can be formed by, for example, consuming a portion of the surface of the tensilely strained layer 520. The dielectric layer 554 can be formed by various methods conventional in the art, e.g., thermal oxidation or a deposition technique.

The gate dielectric 554 can be, for example, a 1.0 to 10.0 nm thick layer of silicon dioxide. Alternative embodiments of the transistor 500 include other suitable dielectric materials, e.g., silicon oxynitride, silicon nitride, a plurality of silicon nitride and silicon oxide layers, or a high-k dielectric. Alternative dielectric materials may be employed when, for example, a thin effective gate oxide thickness is desired, for example, equivalent to a SiO₂ layer thickness of 2.0 nm or less.

The transistor 500, according to principles of the invention, can be implemented as a NMOS or a PMOS component. The transistor 500 can include, for example, different doping types and levels in source, drain, and channel layer regions. A structure can thus include NMOS and PMOS transistors 500, utilizing a shared dual-channel layer, and both NMOS and PMOS components can provide improved channel performance.

With reference to FIG. 6 through FIG. 10, further embodiments of the invention are described. In a broad overview of one of these embodiments, a first semiconductor layer, formed, for example, of Si, is directly bonded to a relatively thin intermediate layer formed of a different semiconductor, for example, of SiGe. The intermediate layer is thin enough to cause relatively minor thermal effects in a device, but is thick enough to place misfit dislocations of the bonded interface at a deep enough location to avoid a substantially adverse electrical effect on a device formed on a substrate that includes the intermediate layer.

For example, a structure including an intermediate layer of relaxed or strained SiGe on a strained silicon layer can be directly bonded to an unstrained silicon substrate. The strained silicon layer can then be utilized as a channel layer for a MOS device. The SiGe layer can be thinner than SiGe layers found in typical virtual substrates, while the bonded interface can reside deeper in a device than a depth required for contact formation and/or a depth required for a channel.

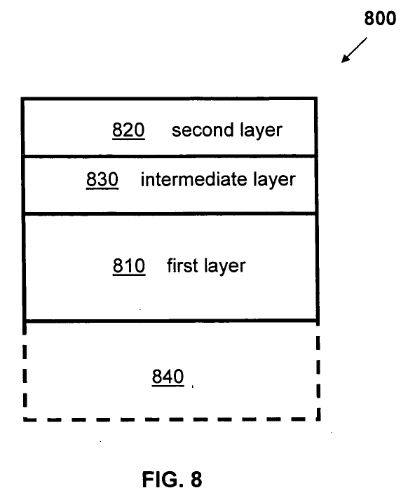

FIG. 6 is a flowchart of an embodiment of a method 600 for making a semiconductor-based structure, according to a broad principle of the invention. Some examples of structures that can be fabricated via the method 600 are described below with reference to FIGS. 8, 9, and 10.

The method 600 includes providing a first layer formed of a semiconductor (Step 610), providing a second layer formed of essentially the same semiconductor as the first layer (Step 620), providing an intermediate layer in direct contact with the second layer (Step 630), and bonding the first layer directly to the intermediate layer (Step 640) by, for example, contacting surfaces of the first and intermediate layers, and annealing to promote direct atomic bonding between the first and intermediate layers. The order herein of the description and/or listing of steps of the method 600 should not be construed to require a particular temporal sequence of events nor to preclude simultaneity of two or more events.

The first layer and the second layer, though formed of the same semiconductor, have different lattice spacings (lattice constants) parallel to the bonded surfaces. The different lattice spacings are associated with different strain states of the first and second layers. The intermediate layer can be unstrained or strained.

A thickness of the intermediate layer can be selected to provide effective thermal conduction for a device formed from the semiconductor structure. One having ordinary skill in the semiconductor device arts will understand how to select a thickness of the intermediate layer, which will be a function of the design and operating parameters of a particular device. Such a device can than have better thermal conduction that prior devices. For example, in one embodiment, a device having a channel in a strained silicon layer on a SiGe intermediate layer has better thermal properties than prior devices formed on a typical SiGe-based virtual substrate.

The intermediate layer can be placed in contact with the second layer prior to, or after, bonding (STEP 640) of the intermediate layer to the first layer. For example, prior to bonding (STEP 640), the intermediate layer can be deposited on the second layer, or the second layer can be deposited on the intermediate layer. Alternatively, for example, after bonding (STEP 640), the second layer can be deposited on the intermediate layer.

The first and intermediate layers can have a common crystallographic orientation after bonding. That is, the first and intermediate layers can be oriented, prior to bonding, so that no tilt or twist misorientation exists between the layers when they are brought into contact and bonded. The layers can be bonded at substantially planar surfaces to provide a bonded interface that is free of voids. Moreover, the bonded surfaces of the two layers are preferably provided with the same crystallographic orientation. Interfacial defects associated with misorientation can be reduced in density or eliminated by reducing or eliminating misorientation prior to bonding.

In alternative embodiments of the invention, the surfaces of the bonded layers have different crystallographic orientations. For example, a (100)-oriented surface can be bonded to (111)-oriented surface, or surfaces that are slightly off-cut from common orientations can be bonded.

The difference in strain, corresponding to a difference in lattice constants, between the first and second layers can manifest itself as a difference in the in-plane lattice spacing (and lattice constant) of the two layers, i.e. along a direction parallel to a plane defined by the layers. For example, if the first layer is formed of unstrained Si, and the second layer is formed of silicon that was strained by a SiGe layer of a virtual substrate, the lattice spacing parallel to the interface will be greater in the second layer than in the first layer.

In some embodiments, according to principles of the invention, the second layer is strained while the first layer is substantially unstrained. Thus, for example, though the two layers have the same crystallographic structure, a lattice constant of the second layer can be distorted in comparison to a corresponding undistorted lattice constant of the first layer.

According to principles of the invention, the first layer can be, for example, a substantially unstrained silicon surface layer provided on a SOI substrate, or can be, for example, a conventional silicon wafer. The second layer can be formed, and strained, by, for example, depositing silicon on a virtual substrate. The virtual substrate can include a strain-inducing surface layer, such as a SiGe layer, on which the silicon second layer is grown. The composition of the SiGe layer can be selected to provide a desired level of strain in the silicon second layer.

Continuing this example, the intermediate layer can be a SiGe layer having a similar composition to the strain-inducing layer of the virtual substrate, and can be formed via deposition on the second layer. The intermediate layer can thus be substantially strain-free.

For example, the strain-inducing substrate layer can be formed by co-depositing silicon and germanium at a temperature in a range of, for example, about 300° C. to about 1000° C. (preferably, about 500° C. to about 600° C.) to improve surface flatness of the SiGe. The second layer can be formed by depositing silicon on the strain-inducing layer at a temperature in a range of, for example, about 300° C. to about 1000° C. (preferably, about 500° C. to about 600° C.) The intermediate layer can then be formed by depositing SiGe on the silicon second layer.

The Ge composition of the intermediate layer can be chosen such that the layer is relaxed, or is compressively- or tensiley-strained. The Ge composition required for these strain states is dependent upon, for example, the Ge composition of the strain-inducing substrate layer, which can be a SiGe layer essentially free of strain.

As described above, CMP processing can be utilized to improve surface smoothness prior to bonding (Step 640).

The surfaces can be bonded (Step 640) by, for example, contacting and annealing. Annealing can promote direct atomic bonding between the surfaces of the first and second layers. For silicon and SiGe bonding, annealing can be performed by heating the first and intermediate layers to a temperature of, for example, greater than about 700° C. For example, annealing can be performed at 800° C. for 2 hours.

Further, the first and intermediate layer surfaces can be treated prior to contacting to make them substantially hydrophobic prior to contacting. Provision of a hydrophobic surface can, prior to bonding, reduce or eliminate formation of oxide on the layer surfaces. A hydrophobic surface can be obtained by, for example, bathing in a hydrofluoric acid (HF) solution, for example, a 10% HF solution in water, by volume. A dip in a HF solution also can remove surface oxides.

To remove organic material and/or particles from the surface of a silicon layer, the silicon can be treated in, for example, 3H₂OSO₄:1H₂O₂ for 5 minutes, then in 50H₂O:1HF for 15 seconds, then in 6H₂O:1HCl:1H₂O₂ for 15 minutes at 60° C., thus producing a hydrophilic surface. The silicon can then be treated in 10H₂O:1HF for 1 minute to remove surface oxide at the surface, rendering the surface hydrophobic.

Since the bonds formed after initial contact can be weak, annealing is desirable after contacting. Annealing at temperatures above about 700° C. can remove hydrogen bonded to surfaces of the first and intermediate layers, and promote the direct bond between the two layers.

A virtual substrate, or other material, on which the second layer was formed, can be removed (Step 650) after bonding the intermediate layer to the first layer, to expose the second layer. Removal of material can commence with mechanical grinding and/or chemical etching. For example, a KOH solution can provide removal of layers and/or portions of layers of a virtual substrate, such as removal of silicon and selective removal of SiGe to an upper concentration level of Ge. For this purpose, 20 wt % KOH at about 65° C. to about 80° C. can be used. To selectively complete removal of a SiGe layer while leaving an adjacent silicon second layer, a chemical etch of nitric acid, acetic acid, and dilute HF (100H₂O:1HF), for example, can be used. One or more etch-stop layers can be provided in contact with the second layer to help control removal of all or part of a virtual substrate.

Additional layers can be deposited on a virtual substrate prior to deposition of the second layer to provide etch stops for material removal to help expose the second layer, or another layer, with minimal damage to the exposed layer. For example, a Si_{0.60}Ge_{0.40} layer can be deposited on a strain-inducing relaxed Si_{0.75}Ge_{0.25} layer prior to deposition of the second layer. Additional layers can be deposited on the Si_{0.60}Ge_{0.40} layer, for example, alternating layers of strained Si and Si_{0.60}Ge_{0.40}. The second layer can then be deposited on the additional layers, and the intermediate layer can then be deposited on the second layer.

An additional layer of strained Si can be used as a selective etch-stop layer or utilized as a device channel. For example, portions of a virtual substrate can be removed by mechanical grinding, and by an etch that selectively stops at the additional layer of strained Si. Then, selective removal of the additional layer of strained Si can proceed by using, for example, an etch of 20 wt % KOH solution.

Moreover, a strain-inducing layer can have a similar composition to an intermediate layer. Continuing the above example, the strain-inducing layer can be a relaxed Si_{0.75}Ge_{0.25} layer to match the intermediate layer formed of Si_{0.75}Ge_{0.25}. The intermediate layer can then be substantially strain free, while the second layer will have a strain-state controlled by the relaxed Si_{0.75}Ge_{0.25} layer.

The method 600 can employ thin-film deposition techniques known to one having ordinary skill in the semiconductor fabrication arts. The techniques can be modified to improve surface planarity of the deposited films to mitigate the poor planarity that can arise during deposition of strained films. A strain-inducing layer and/or a second layer, and/or an intermediate layer, can be deposited, for example, at relatively low temperatures to improve planarity. For example, a strained silicon second layer may be deposited at about 650° C., substantially without causing undulations, on a SiGe strain-inducing layer having a Ge atomic concentration of 20%, while a Si second layer deposition temperature of about 550° C. is preferable for an underlying SiGe layer having a Ge concentration of 50%.

A strain-inducing layer can be, for example, a graded SiGe layer, or can be formed on a graded SiGe layer. The graded SiGe layer can have a grading rate of, for example, 10% Ge/μm, and a thickness in a range of, for example, 2 μm to 9 μm. The graded layer may be grown at a temperature in a range of, for example, 600° C. to 1100° C.

A strain-inducing layer, on which a strained second layer can be grown, can be a relaxed SiGe layer, which can in turn be grown on a graded SiGe layer. The relaxed layer can be formed of Si₁₋ₓGeₓ with a uniform concentration having x in a range of about 20% to 90%. The relaxed layer can have a thickness in a range of, for example, about 0.2 μm to about 2.0 μm. A relaxed or strained SiGe strain-inducing layer can support growth of a strained silicon second layer, the layers having respective thickness values in a range of, for example, 0.5 nm to about 500 nm, and 0.5 nm to about 20 nm. An intermediate layer grown on the strain silicon second layer can have a thickness selected in response to planned device structures.

Deposition may be accomplished, for example, by any suitable epitaxial deposition system, including, but not limited to, atmospheric-pressure CVD (APCVD), low- (or reduced-) pressure CVD (LPCVD), ultra-high-vacuum CVD (UHVCVD), or by molecular beam epitaxy. The epitaxial growth system may be a single-wafer or multiple-wafer batch reactor. The growth system also may utilize a low-energy plasma to enhance the layer growth kinetics.

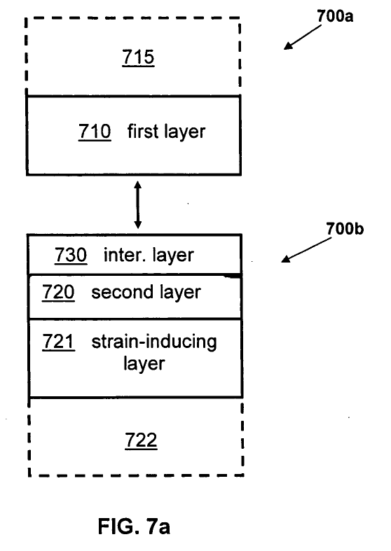

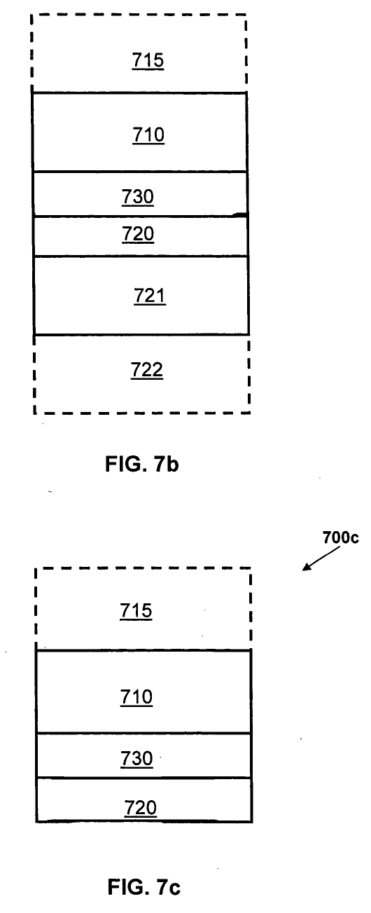

Now referring to FIGS. 7a, 7b, and 7c, embodiments of structures that illustrate various steps of the method 600 are described. FIG. 7a is a cross-sectional view of a first substrate 700a and a second substrate 700b at a time prior to bonding. The first substrate 700a includes a first layer 710, and can include one or more additional substrate layers 715. The first layer 710 can be, for example, a conventional silicon wafer.

The second substrate 700b includes a second layer 720 (e.g., a strained silicon layer) formed on a strain-inducing layer 721 (e.g., a relaxed SiGe layer), and an intermediate layer (e.g., a relatively thin relaxed or strained SiGe layer) 730 formed on the second layer 720. The second substrate 700b can include one or more additional layers 722. The strain-inducing layer 721 and the one or more additional layers 722 can be layers of a virtual substrate.

FIG. 7b is a cross-sectional diagram of the substrates 700a, 700b as they appear after bonding of the first layer 710 to the intermediate layer 730, as accomplished, for example, by bonding (Step 640) as described above for the method 600. Misfit dislocations can be substantially confined to the bonded interface, rather than residing at an interface of the second layer, thus improving the performance of devices that utilize the second layer 720.

The intermediate layer 730 can have its thickness selected to provide good thermal characteristics while being sufficiently thick to permit device fabrication without the substantial presence of misfit dislocations in an active device region and/or a region that can lead to short circuits in a device. For example, the thickness can be selected to place the bonded interface at a greater depth than a depth of a bottom interface of a contact.

FIG. 7c is a cross-sectional diagram that illustrates a semiconductor-based structure 700c that remains after removal of the strain-inducing layer 721 and any other layers 722. The structure 700c can be used, for example, to fabricate semiconductor-based devices. A device can be formed, for example, on and including the second layer 720.

As described in more detail with reference to FIGS. 8, 9 and 10, the method 600 can include steps relating to formation of one or more device components having n-type channels and/or one or more device components having p-type channels. For example, in relation to forming a n-type channel component, the method 600 can include forming a gate dielectric layer adjacent to the exposed second layer 720 (e.g., a tensilely strained silicon layer) of the semiconductor-based structure 700c, and then forming a gate in contact with the gate dielectric layer for mediating a n-type channel in the second layer 720.

FIG. 8 is a cross-sectional view of a portion of an embodiment of a semiconductor-based structure 800, according to principles of the invention. The structure 800 includes a first layer 810 and an intermediate layer 830 directly bonded to each other, and a strained second layer 820 adjacent in contact with the intermediate layer 830. The structure 800 can include a substrate 840 in contact with the first layer 810. The structure 800 can be fabricated by, for example, the methods described above.

The first and intermediate layers 810 and 830 are formed of different materials, and can have different lattice constants relative to each other. For example, the intermediate layer 830 can be formed of relaxed SiGe or SiGe strained along a direction parallel to the interface between the layers 810, 830, while the first layer 810 can be formed of unstrained silicon.

The second layer 820 can have the same in-plane lattice spacing as the intermediary layer 830, and can be formed, for example, of strained silicon. The first layer 810 and the second layer 820 can thus be composed of essentially the same material. The structure 800 can be used in the fabrication of electronic devices, as described with reference to FIG. 10.

Alternatively, in another embodiment, the second layer 820 is compressed Ge on a relaxed or strained SiGe intermediate layer 830, and the first layer 810 is unstrained Ge. In this example, a compressed Ge second layer 820 can be formed on substrates such as Si, SiGe, or Ge, or any suitable virtual substrate. The second layer 820 can then be transferred to another substrate, as described above.

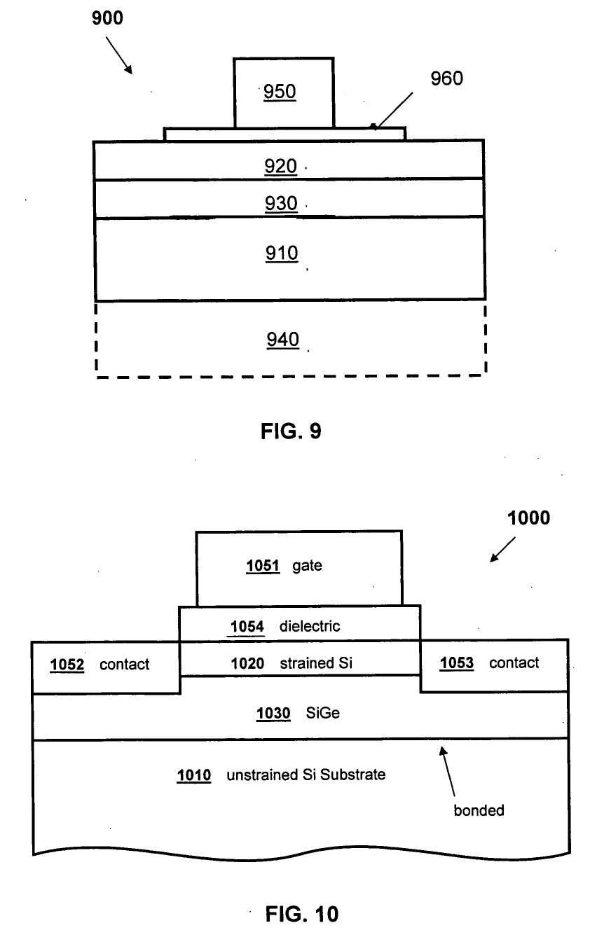

FIG. 9 is a cross-sectional view of an embodiment of an electronic device 900, according to principles of the invention. The device 900 can be based on the structure 800, and can be fabricated via the method 600.

The device 900 includes an unstrained silicon first layer 910, a relatively thin relaxed or strained SiGe intermediate layer 930 bonded to the unstrained silicon first layer 910, a strained silicon second layer 920 in contact with the intermediate layer 930, a gate contact 950, and a gate dielectric layer 960 disposed between the strained silicon second layer 920 and the gate contact 950.

Application of a voltage to the gate contact can be used to control a channel in the strained silicon second layer 920. The device 900 can include a substrate 940 in contact with the unstrained silicon layer 910. Alternatively, for example, the unstrained silicon first layer 910 can be associated with a conventional silicon wafer.

The strained silicon second layer 920 can be shared by two or more electronic components, and can be continuous or discontinuous depending on the fabrication steps of a particular embodiment of a device 900. For example, a shared second layer 920, or portions of the second layer 920, can extend continuously between two or more components, or individual devices may be associated with spaced portions of the layer 920. Various implementations of the invention can improve carrier mobilities, for example, the mobility of holes in a channel formed in the second layer 920.

FIG. 10 is a cross-sectional view of an embodiment of a transistor 1000 that can be included in a device, such as the device 900, according to principles of the invention. The transistor 1000 includes a gate contact 1051, source and drain contacts 1052, 1053, such as silicide contacts, a gate dielectric layer 1054, an unstrained silicon first layer 1010, an unstrained or strained SiGe intermediate layer 1030 bonded directly to the unstrained silicon layer 1010, and a tensilely strained silicon second layer 1020 on the unstrained or strained SiGe intermediate layer 1030.

The tensilely strained silicon second layer 1020, the unstrained silicon first layer 1010, and the unstrained or strained SiGe intermediate layer 1030 may be shared with other components in a device. The thicknesses of the SiGe intermediate layer 1030 and the source and drain contacts 1052, 1053 have been chosen so that a lower extent of the source and drain contacts 1052, 1053 does not reach the bonded interface between the first layer 1010 and the intermediate layer 1030. Thus, dislocations residing in the bonded interface are in effect moved away from the lower interface of the strained Si second layer 1020. The thickness of the intermediate layer 1030 is also kept thin enough to cause an acceptable impact on the thermal behavior of the transistor 1000.

The intermediate layer 1030 can have a uniform composition, or can include more than one layer. For example, the intermediate layer 1030 can include a thin strained SiGe layer and a thin unstrained SiGe layer. The second layer can be grown on the thin strained SiGe layer. The second layer 1020 and the thin strained SiGe layer can then provide, for example, a surface channel and/or a buried channel for the device 1000.

The gate contact 1051 can include, for example, doped conductive polycrystalline silicon and/or a silicide. Alternatively, the gate contact 1051 may be formed of other conductive materials, such as, polycrystalline SiGe; a metal, e.g., titanium (Ti), tungsten (W), molybdenum (Mo), tantalum (Ta), or iridium (Ir), or metal compounds that provide an appropriate workfunction, e.g., titanium nitride (TiN), titanium silicon nitride (TiSiN), tungsten nitride (WN), tantalum nitride (TaN), tantalum silicide (TaSi), nickel silicide (NiSi), or iridium oxide (IrO₂).

The tensilely strained second layer 1020 and the SiGe intermediate layer 1030 may be formed, for example, by epitaxial growth, as described above. The source and drain contacts 1052, 1053 can be formed, for example, by depositing a metal layer and reacting the metal layer with the second layer 1020, and, optionally, the intermediate layer 1030.

The gate dielectric 1054 is formed on the tensilely strained layer 1020. The gate dielectric 1054 can be formed by, for example, consuming a portion of the surface of the tensilely strained layer 1020. The dielectric layer 1054 can be formed by any suitable method including, for example, conventional methods of thermal oxidation and/or deposition.

The gate dielectric 1054 can be, for example, a 1.0 to 10.0 nm thick layer of silicon dioxide. Alternative embodiments of the transistor 1000 include other suitable dielectric materials, e.g., silicon oxynitride, silicon nitride, a plurality of silicon nitride and silicon oxide layers, or a high-k dielectric. Alternative dielectric materials may be employed when, for example, a thin effective gate oxide thickness is desired, for example, equivalent to a SiO₂ layer thickness of 2.0 nm or less.

The transistor 1000 can be implemented as a NMOS or a PMOS component. The transistor 1000 can include, for example, different doping types and levels in source, drain, and channel layer regions. A structure can thus include NMOS and PMOS transistors 1000, utilizing a shared dual-channel layer, and both NMOS and PMOS components can provide improved channel performance.

Having thus described several aspects of at least one embodiment of this invention, it is to be appreciated various alterations, modifications, and improvements will readily occur to those skilled in the art. For example, semiconductor layers can be formed from elemental, alloy, and compound semiconductors other than Si, Ge, and SiGe. For example, layers formed from essentially the same semiconductor can be formed from a semiconductor that includes at least two group III and V elements, such as indium gallium arsenide, indium gallium phosphide, and gallium arsenide, or from a semiconductor that includes at least two group II and VI elements, such as zinc selenide, sulphur, cadmium telluride, and mercury telluride. Such alterations, modifications, and improvements are intended to be part of this disclosure, and are intended to be within the spirit and scope of the invention. Accordingly, the foregoing description and drawings are by way of example only.

1. A semiconductor-based structure, comprising:
a first layer consisting essentially of a semiconductor;
a second layer consisting essentially of the semiconductor, and having a different lattice spacing than a lattice spacing of the first layer; and
an intermediate layer disposed between the first and second layers, and bonded directly to the first layer, and in direct contact with the second layer, and having a substantially different composition than a composition of the semiconductor, and a thickness that provides effective thermal conduction.

2. The semiconductor-based structure of claim 1, wherein the semiconductor is silicon, and the lattice spacing of the second layer is greater than the lattice spacing of the first layer.

3. The semiconductor-based structure of claim 2, wherein the lattice spacing of the second layer is different by a value in a range of about 0.04% to about 2% from the lattice spacing of the first layer.

4. The semiconductor-based structure of claim 2, wherein the intermediate layer consists essentially of silicon and germanium.

5. The semiconductor-based structure of claim 4, wherein the intermediate layer has a substantially spatially uniform composition.

6. The semiconductor-based structure of claim 1, wherein the thickness of the intermediate layer is less than 0.3 micrometers.

7. The semiconductor-based structure of claim 1, wherein the first and intermediate layers are bonded at an interface located at a greater depth than a depth of a contact to the intermediate layer.

8. The semiconductor-based structure of claim 1, wherein the intermediate layer has a lattice spacing substantially the same as the lattice spacing of the second layer.

9. The semiconductor-based structure of claim 1, wherein the first layer is substantially strain-free, and the lattice spacing of the second layer is associated with a strain of the second layer parallel to a plane defined by an interface of the second layer.

10. The semiconductor-based structure of claim 1, wherein an interface at which the first and intermediate layers are bonded is defined by an array of edge dislocations that substantially accommodate the lattice spacing difference between the first and second layers so that an interface between the second and intermediate layers is substantially free of misfit dislocations.

11. The semiconductor-based structure of claim 10, wherein the array of edge dislocations comprises an array of substantially parallel dislocations having a spacing in a range of about 20 nm to about 1000 nm.

12. The semiconductor-based structure of claim 1, wherein the first and intermediate layers are bonded at an interface that is substantially free of dislocations that accommodate tilt and twist crystallographic misorientations between the first and intermediate layers.

13. The semiconductor-based structure of claim 1, wherein the semiconductor is germanium, and the lattice spacing of the second layer is less than the lattice spacing of the first layer.

14. An electronic device, comprising:
a substantially strain-free substrate layer consisting essentially of silicon;
a tensilely strained layer consisting essentially of silicon;
an intermediate layer disposed between the substantially strain-free substrate layer and the tensilely strained layer, and consisting essentially of silicon and germanium, wherein the intermediate layer is directly bonded to the substantially strain-free substrate layer, and in contact with the tensilely strained layer, and has a thickness that provides effective thermal conduction;
a gate dielectric layer adjacent to the tensilely strained layer; and
a gate in contact with the gate dielectric layer.

15. The electronic device of claim 14, further comprising a source contact and a drain contact each in direct contact with the intermediate layer, and having substantially no direct contact with the substantially strain-free substrate layer.

16. The electronic device of claim 15, wherein the thickness of the intermediate layer is less than about 0.3 micrometer.

17. The electronic device of claim 14, wherein the intermediate layer is substantially strain free.

18. A method for making a semiconductor-based structure, the method comprising:
providing a first layer defining a surface, and consisting essentially of a semiconductor;
providing a second layer consisting essentially of the semiconductor, the second layer having a different lattice spacing parallel to the surface of the first layer than a lattice spacing of the first layer parallel to the surface of the first surface;
providing an intermediate layer having a thickness that provides effective thermal conduction, and in direct contact with the second layer; and
bonding the surface of the first layer directly to a surface of the intermediate layer.

19. The method of claim 18, wherein the semiconductor is silicon.

20. The method of claim 19, wherein the intermediate layer consists essentially of germanium and silicon.

21. The method of claim 19, wherein the lattice spacing of the second layer is greater than an equilibrium lattice spacing of silicon.

22. The method of claim 18, wherein providing the second layer comprises depositing the semiconductor on a strain-inducing substrate layer comprising at least one material other than the semiconductor.

23. The method of claim 22, wherein the strain-inducing substrate layer consists essentially of germanium and silicon.

24. The method of claim 23, wherein the intermediate layer and the strain-inducing layer have essentially a same composition.

25. The method of claim 22, wherein providing the intermediate layer comprises depositing the intermediate layer on the second layer.

26. The method of claim 25, wherein the intermediate layer is essentially strain-free.

27. The method of claim 22, wherein the strain free substrate layer has a substantially same composition as the intermediate layer.

28. The method of claim 22, further comprising removing the strain-inducing substrate layer after bonding to expose the second layer.
